(19) United States
(12) Patent Application Publication
(10) Pub. No.: US 2023/0136511 A1
(43) Pub. Date: May 4, 2023

(54) QUANTUM DOT FILM, METHOD FOR PRODUCING QUANTUM DOT FILM, OPTO-ELECTRONIC DEVICE INCLUDING QUANTUM DOT FILM, AND IMAGE SENSOR INCLUDING OPTO-ELECTRONIC DEVICE

(71) Applicant: SAMSUNG ELECTRONICS CO., LTD., Suwon-si (KR)

(72) Inventor: Kyungsang CHO, Gwacheon-si (KR)

(73) Assignee: SAMSUNG ELECTRONICS CO., LTD., Suwon-si (KR)

(21) Appl. No.: 17/732,007

(22) Filed: Apr. 28, 2022

(30) Foreign Application Priority Data
Nov. 2, 2021 (KR) 10-2021-0149021

(51) Int. Cl. H01L 51/50; H01L 51/00; H01L 51/52

(52) U.S. Cl. CPC H01L 51/502; H01L 51/0091; H01L 51/0079; H01L 51/5203; H01L 51/002

(57) ABSTRACT

Provided is a method for producing a quantum dot (QD) film, the method including applying a QD solution on a surface of a base portion to form a QD array, performing cross-linking on the formed QD array, doping QDs included in the QD array by reacting the QDs included in the QD array on which cross-linking is completed with a metal solution including a doping metal, and cleaning the QD array to obtain a QD film including the doped QDs.

### CROSS-REFERENCE TO RELATED APPLICATION

This application is based on and claims priority under 35 U.S.C. § 119 to Korean Patent Application No. 10-2021-0149021, filed on Nov. 2, 2021, in the Korean Intellectual Property Office, the disclosure of which is incorporated by reference herein in its entirety.

### BACKGROUND

### 1. Field

Example embodiments of the present disclosure relate to a quantum dot (QD) film, a method for producing a QD film, and an opto-electronic device including the QD film, and an image sensor including the opto-electronic device.

### 2. Description of Related Art

A QD is a nanocrystal of a semiconductor material having a nano size, and is a material exhibiting a quantum confinement effect. For example, colloidal QDs exhibit different band gaps according to sizes thereof due to the quantum confinement effect at the nano size. Due to the bandgap characteristics according to sizes of QDs, QDs have been used in various opto-electronic devices such as light emitting devices and light receiving devices. For example, QDs have been applied to light emitting devices such as QD-light emitting diodes (LEDs) and QD-TVs and QD-displays including QD-LEDs or light receiving devices such as QD-photodetectors and QD-solar cells.

In addition to bandgap control based on a change in size of QDs, it is important to control the semiconductor properties of QDs, in particular, p-type and n-type characteristics. The Fermi level of QDs, the valence band energy level of QDs, and the conduction band energy level of QDs based on control of the p-type and n-type characteristics are important properties to be considered in developing QD-LEDs, QD-photodetectors, QD-solar cells.

### SUMMARY

One or more example embodiments provide quantum-dot (QD) films of which an energy band level is changed by doping QDs, and a method for producing the QD films.

One or more example embodiments also provide opto-electronic devices and image sensors having low dark noise, high signal-to-noise (S/N) ratio, and a fast response rate due to use of a QD film of which an energy band level is changed by doping QDs as a light absorption material.

Additional aspects will be set forth in part in the description which follows and, in part, will be apparent from the description, or may be learned by practice of example embodiments.

According to an aspect of an example embodiment, there is provided a method for producing a quantum dot (QD) film, the method including applying a QD solution on a surface of a base portion to form a QD array, performing cross-linking on the formed QD array, doping QDs included in the QD array by reacting the QDs included in the QD array on which cross-linking is completed with a metal solution including a doping metal, and cleaning the QD array to obtain a QD film including the doped QDs.

The metal solution may include a solution in which a doping metal precursor and didodecyldimethylammonium bromide (DDAB) are dissolved.

The metal solution may include a solution in which a metal salt including a doping metal and DDAB are added and dissolved.

The metal salt may include one of CuCl₂, AgNO₃, AgCl, and AuCl₃.

The performing of cross-linking may use a solution in which a linker is dissolved.

The linker may include at least one of diamine and dithiol.

The QD solution may include at least one of organic ligand surfactant QDs, halide treated QDs, metal treated QDs, and metal chalcogenide complex treated QDs.

The QDs of the QD solution may be intrinsic n-type InAs or InSb QDs, and the doped QDs may be of an n-type or p-type.

According to another aspect of an example embodiment, there is provided a quantum dot (QD) film including an array of QDs, wherein the array of QDs is formed on a surface of a base portion, and wherein the array of QDs includes cross-links and doped QDs formed by reacting the QDs with a precursor of a doping metal.

The array of QDs may include a QD stack of two or more layers.

The cross-link may include at least one of diamine and dithiol.

The QDs may include at least one of organic ligand surfactant QDs, halide treated QDs, metal treated QDs, and metal chalcogenide complex treated QDs.

The QDs may be InAs or InSb QDs, and the doping metal may include one of Ag, Au, and Cu.

An opto-electronic device may include a base portion, a first electrode and a second electrode spaced apart from each other on an upper surface of the base portion, and a quantum dot (QD) layer between the first electrode and the electrode on the base portion, the QD layer including a plurality of QDs, wherein the QD layer includes the QD film comprising the doped QDs produced by the method.

The QDs included in the QD solution may be of intrinsic n-type InAs or InSb QDs, and the doped QDs may be of an n-type or p-type.

The base portion may include a first semiconductor layer doped with a first conductivity type, and a second semiconductor layer disposed on an upper surface of the first semiconductor layer and doped with a second conductivity type different from the first conductivity type, wherein the upper surface of the base portion corresponds to an upper surface of the second semiconductor layer, wherein the first electrode and the second electrode are electrically connected to the second semiconductor layer, and wherein the QD layer is between the first electrode and the second electrode on the second semiconductor layer and may include QDs doped with a single conductivity type.

The opto-electronic device may further include a first doped region and a second doped region spaced apart from each other in the second semiconductor layer and doped with a concentration different from a concentration of the second semiconductor layer, wherein the first electrode and the second electrode may be electrically connected to the first doped region and the second doped region, respectively.

According to another aspect of an example embodiment, there is provided an image sensor including an array of a plurality of opto-electronic devices, and a driving circuit configured to output a signal from each of the opto-electronic devices, wherein each of the opto-electronic devices includes a base portion, a first electrode and a second electrode spaced apart from each other on an upper surface of the base portion, and a quantum dot (QD) layer between the first electrode and the electrode on the base portion, the QD layer including a plurality of QDs, wherein the QD layer includes the QD film including the doped QDs produced by the method.

The base portion may include a first semiconductor layer doped with a first conductivity type, and a second semiconductor layer disposed on an upper surface of the first semiconductor layer and doped with a second conductivity type different from the first conductivity type, wherein the upper surface of the base portion corresponds to an upper surface of the second semiconductor layer, wherein the first electrode and the second electrode are electrically connected to the second semiconductor layer, and wherein the QD layer is between the first electrode and the second electrode on the second semiconductor layer and may include QDs doped with the first conductivity type.

The image sensor may further include a first doped region and a second doped region spaced apart from each other in the second semiconductor layer and doped with a concentration different from a concentration of the second semiconductor layer, wherein the first electrode and the second electrode may be electrically connected to the first doped region and the second doped region, respectively.

### BRIEF DESCRIPTION OF THE DRAWINGS

The above and/or other aspects, features, and advantages of example embodiments will be more apparent from the following description taken in conjunction with the accompanying drawings, in which:

FIG. 1 is a flowchart illustrating a method for producing a quantum dot (QD) film according to an example embodiment;

FIGS. 2A, 2B, 2C, and 2D illustrate QD arrays in operations S10, S20, S30, and S40 of FIG. 1, respectively;

FIG. 3A illustrates gas chromatography (GC) mass-spectrometer data before cross-linking of an InAs QD film, FIG. 3B illustrates GC mass spectrometer data after cross-linking of the InAs QD film overlaid on existing data, and FIG. 3C illustrates a mass spectrum of a portion A of FIG. 3B in detail;

FIG. 4 is a graph showing a shift of absorbance peaks before and after Ag doping of InAS QD films by using a method for producing a QD film according to an example embodiment;

FIG. 5 illustrates an existing solution doping method as a related example;

FIG. 6 is a graph showing absorbance characteristics when InAs QDs are doped in a toluene solution by applying a related solution doping method;

FIG. 7 schematically illustrates a structure of an opto-electronic device according to an example embodiment;

FIG. 8 illustrates a difference in reaction rate according to whether QDs are doped in an opto-electronic device having a QD-Si junction field effect transistor (JFET) structure;

FIGS. 9 and 10 illustrate changes in photocurrents detected in a related example sample and an example sample of FIG. 8;

FIG. 11 illustrates a difference in rise time of photocurrents detected in the related example sample and the example sample of FIG. 8;

FIGS. 12, 13, 14, and 15 are cross-sectional views schematically illustrating structures of opto-electronic devices according to various example embodiments;

FIG. 16 is a cross-sectional view schematically illustrating a structure of an image sensor including a plurality of opto-electronic devices according to an example embodiment;

FIG. 17 is a block diagram illustrating a schematic structure of an electronic device including an image sensor according to an example embodiment;

FIG. 18 is a block diagram illustrating a schematic structure of a camera module included in an electronic device of FIG. 17; and

FIGS. 19 and 20 illustrate examples of an electronic device including an image sensor according to an example embodiment.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, example embodiments are described in detail with reference to the accompanying drawings. In the following drawings, like reference numerals refer to like components, and the size of each component in the drawings may be exaggerated for clarity and convenience of description. The embodiments described herein are merely examples, and various modifications may be made from these embodiments.

When it is described that a certain component is “above” “on”, below, or left or right of another component, the certain component may be directly above, below, or left or right of another component, or a third component may be interposed therebetween. The singular expressions include plural expressions unless the context clearly dictates otherwise. When a part “includes” a component, it may indicate that the part does not exclude another component but may further include another component, unless otherwise stated.

The use of the terms “a” and “an” and “the” and similar referents may cover both the singular and the plural. The steps constituting a method may be performed in any suitable order unless there is a clear statement that the steps in the method should be performed in the order described, without being limited to the described order.

In addition, the term, such as “ . . . unit” or “module,” disclosed in the specification indicates a unit for processing at least one function or operation, and this may be implemented by hardware, software, or a combination thereof

The connecting lines, or connectors shown in the various figures presented are intended to represent exemplary functional relationships and/or physical or logical couplings between the various elements. It should be noted that many alternative or additional functional relationships, physical connections or logical connections may be present in a practical device

In addition, the use of all examples and exemplary terms is merely for describing technical ideas in detail, and the scope of the present disclosure is not limited by these terms unless limited by claims.

In a method for producing a QD film according to an example embodiment, a QD solution is applied on a surface of a base portion to form a QD array, cross-linking is performed on the QD array, QDs of the QD array on which cross-linking is completed is reacted with a metal solution including a doping metal to dope the QDs, and thereafter, the QD array is cleaned to obtain a QD film including the doped QDs.

Here, the QD array is formed in the form of a thin film on the surface of the base portion, and thus, QD doping is performed on the QD array in the form of a thin film. In the QD array, QDs may be arranged in a single layer or may be stacked in two or more layers. As such, doping is performed on a single-layer QD array or a QD array in which QDs are stacked in two or more layers, so doping may be performed on all types of QDs without limitation on QD materials, whether the QDs are dissolved in a solvent, and ligand types.

That is, for example, in the case of doping the QDs through a reaction in a solution, doping may be performed only on QDs formed of a specific material soluble in a reaction solvent. The method for producing a QD film according to an example embodiment may be universally applied to doping all kinds of QDs.

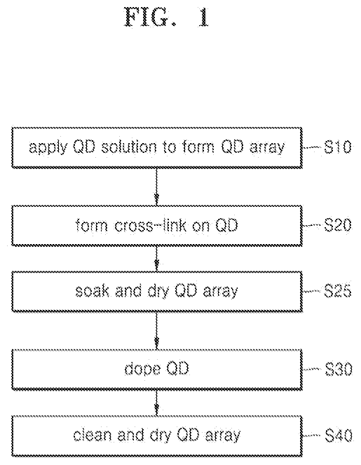

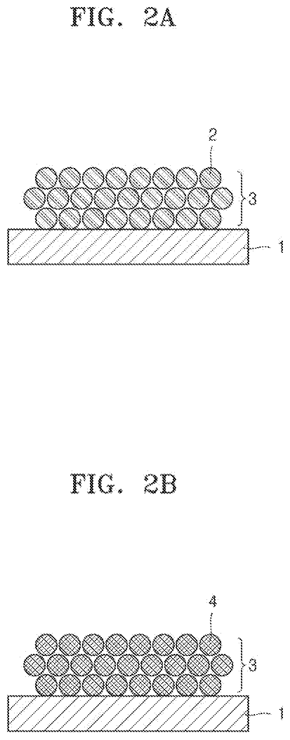

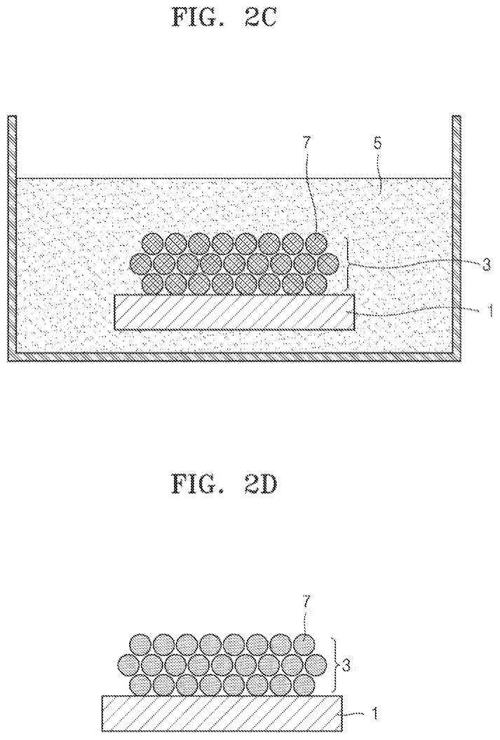

FIG. 1 is a flowchart illustrating a method for producing a QD film according to an example embodiment. FIGS. 2A to 2D illustrate a QD array in operations S10, S20, S30, and S40 of FIG. 1, respectively.

Referring to FIG. 1, first, a QD solution is prepared, and the prepared QD solution is applied on the surface of the base portion to form a QD array constituting a QD film (S10). FIG. 2A illustrates a QD array 3 formed by applying the QD solution on the surface of the base portion 1.

The QD solution may be applied on the surface of the base portion 1 by a method such as spin coating. The QD solution for application is a solution obtained by dispersing QDs in a solvent, and the QDs applied on the surface of the base portion 1 may be colloidal QDs formed using a colloidal solution.

According to a QD film and a producing method thereof according to an example embodiment, there is no limitation on the type of QDs and ligands, and the type of solvent constituting the QD solution. The QD solution may include, for example, at least one of organic ligand surfactant QDs, halide treated QDs, metal treated QDs, and metal chalcogenide complex treated QDs.

QDs may be a nano-size structure formed of a semiconductor (inorganic semiconductor). The QDs may have a diameter of several tens of nm or less, for example, a diameter of about 10 nm or less. For example, the QDs may have a diameter of about 1 nm to about 10 nm.

The QDs may include, for example, at least one of a group II-VI-based semiconductor, a group III-V-based semiconductor, a group IV-VI-based semiconductor, a group IV-based semiconductor, and graphene QDs. QDs of group II-VI-based semiconductors may include one selected from, for example, a binary compound such as ZnS, ZnSe, ZnTe, CdS, CdSe, CdTe, ZnO, HgS, HgSe, and HgTe, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, and HgZnSe, a quaternary compound such as CdHgZnTe, CdZnSeS, CdZnSeTe, CdZnSTe, CdHgSeS, CdHgSeTe, CdHgSTe, HgZnSeS, HgZnSeTe, and HgZnSTe, and a combination thereof. QDs of group III-V-based semiconductors may include one selected from, for example, a binary compound such as GaN, GaP, GaAs, GaSb, AlN, AlP, AlAs, AlSb, InN, InP, InAs, and InSb, a ternary compound such as GaNP, GaNAs, GaNSb, GaPAs, GaPSb, AlNP, AlNAs, AlNSb, AlPAs, AlPSb, InNP, InNAs, InNSb, InPAs, and InPSb, a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, and a combination thereof. QDs of group IV-VI-based semiconductors may include one selected from, for example, a binary compound such as SnS, SnSe, SnTe, PbS, PbSe, and PbTe, a ternary compound such as SnSeS, SnSeTe, SnSTe, PbSeS, PbSeTe, PbSTe, SnPbS, SnPbSe, and SnPbTe, a quaternary compound such as SnPbSSe, SnPbSeTe, and SnPbSTe, and a combination thereof. QDs of the group IV-based semiconductor may include, for example, Si, Ge, SiGe, SiC, or a combination thereof. The graphene QDs may be QDs formed of graphene. In addition, QDs may have a core-shell structure having a core portion and a shell portion, or may have a particle structure without a shell (e.g., a core-only structure). The core-shell structure may have a single-shell or a multi-shell. The multi-shell may be, for example, a double-shell. In addition, QDs may include an alloy. An organic ligand or an inorganic ligand may be present on the surface of the QD.

A QD array 3 formed by applying a QD solution on a surface of the base portion 1 may have a structure arranged to form a stack of two or more layers, as shown in FIG. 2A. However, embodiments are not limited thereto, and the QD array 3 may be formed in a structure in which QDs are arranged in a single layer.

In this manner, after the QD array 3 constituting a QD film is formed through an application process such as spin coating, cross-linking may be performed on the QD array 3 to form a cross-link in the QD (S20).

The cross-linking process may be performed by soaking the QD array 3 in a linker solution in which a linker is dissolved in a solvent such as methanol, or spin coating or spray coating the linker solution on the QD array 3.

When the QD array 3 is subjected to the cross-linking process, a cross-link may be formed in the QDs. Comparing FIG. 2A with FIG. 2B, the QD 4 represents a QD including a cross-link by performing a cross-linking process, and the QD 2 represents a QD before the cross-linking process.

In the cross-linking process in operation S20, a solution in which a linker is dissolved in a solvent such as methanol may be used. As the linker, for example, diamine, dithiol, or the like may be used. For example, during cross-linking, a solution in which a linker such as diamine or dithiol is dissolved in methanol or the like about 10 mM may be used.

In this manner, the QD film including the QD array 3 may be stabilized by the cross-linking process performed using the solution in which a linker such as diamine or dithiol is dissolved in a solution such as methanol, etc., and in this case, the QDs may include a cross-link. Whether the QDs includes a cross-link may be checked by, for example, a component analysis (inductively coupled plasma (ICP)), X-ray photoelectron spectroscopy (XPS), nuclear magnetic resonance (NMR), gas chromatography (GC) mass-spectrometer, and the like.

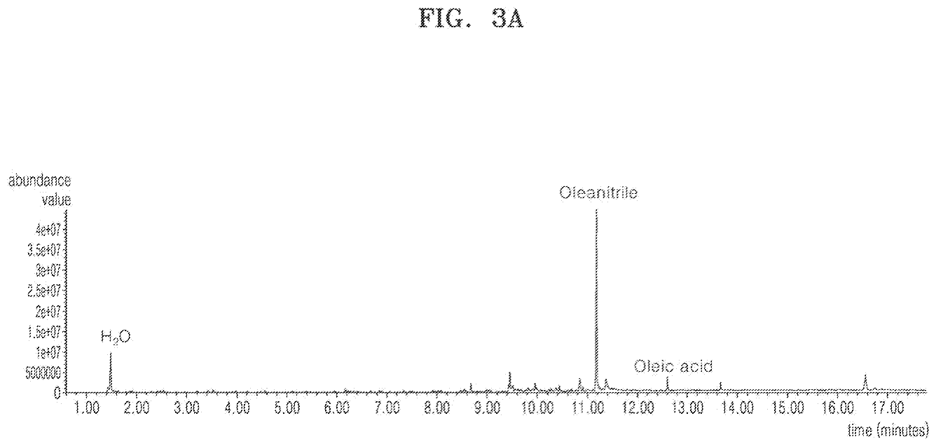

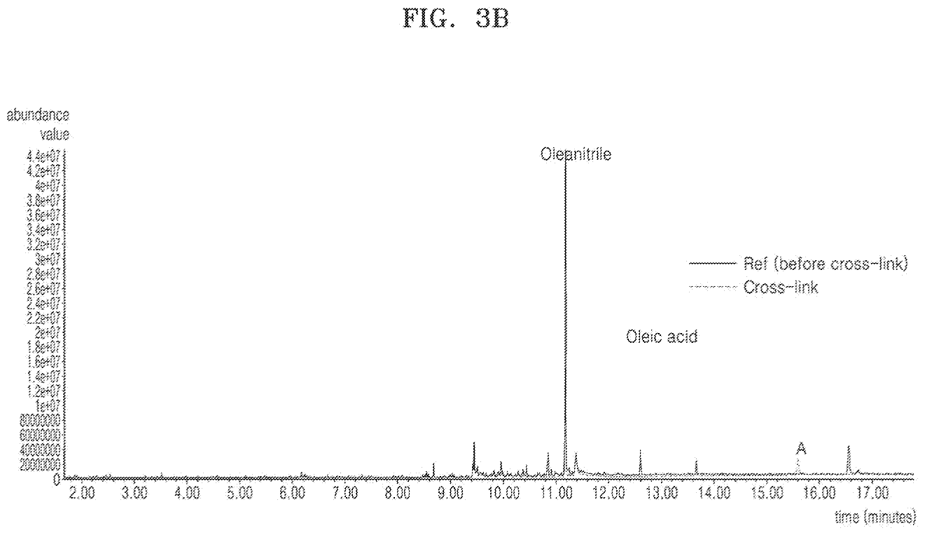

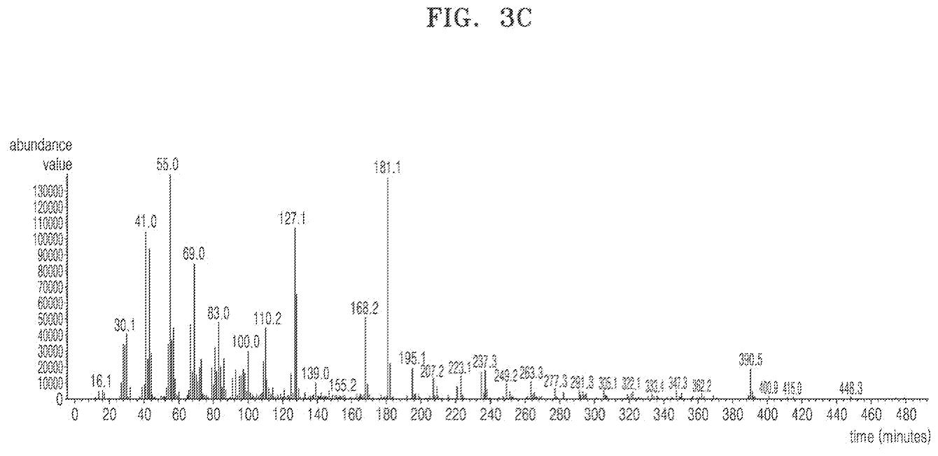

FIG. 3A illustrates GC mass-spectrometer data before cross-linking of an InAs QD film, and FIG. 3B illustrates GC mass spectrometer data after cross-linking of the InAs QD film overlaid on existing data. FIG. 3C illustrates a mass spectrum of a portion A of FIG. 3B.

FIGS. 3A and 3B comparatively illustrate that a new peak is generated near the portion ‘A’ of FIG. 3B after performing the cross-linking. Referring to FIG. 3C, which separately illustrates a mass spectrum of the portion A, a peak having about 390 mass was checked, indicating that there may be a combination of oleylamine and 1,7 diaminoheptane or a structure in which three 1,7diaminoheptanes are bonded.

FIGS. 3A to 3C illustrate results when a total ion chromatogram (TIC)-pyrolyzer is heated to about 400° C., which may be obtained by heating a sample to 400° C., collecting gases, and performing thermal analysis thereon. In FIGS. 3A and 3B, the horizontal axis represents heating time in minutes, and the vertical axis represents a value measured by the instrument as abundance and corresponds to the intensity. Because GC mass spectrometer performs qualitative analysis, a magnitude of a value on the vertical axis does not have a significant meaning, and a position (time) of the horizontal axis is important. In FIG. 3C, the horizontal axis of the spectrum represents a mass/charge ratio as m/z, and the vertical axis represents abundance.

During cross-linking, unreacted or excess linker molecules and the like may be soaked in, for example, a pure solution, for example, a pure methanol solution, or the like, to be removed, and drying may be performed (S25). Drying may be performed, for example, by annealing or the like. Operation S25 may be omitted.

Next, the QDs 4 of the QD array 3 in which the cross-linking is completed may be doped (S30). Referring to FIG. 2C, the QDs of the QD array 3 may be reacted with a metal solution including a doping metal to dope the QDs. In FIG. 2C, reference numeral 7 denotes a doped QD.

Referring to FIG. 2C, for example, QD doping may be performed by soaking the QD array 3 and the entire base portion 1 on which the QD array 3 is formed may be in a metal solution 5 contained in a container. As another example, instead of soaking the QD array 3 and the entire base portion 1 in the metal solution 5, QD doping may be performed by adding the metal solution 5 to the QD array 3. For example, the metal solution 3 may be added to the QD array 3 by spin coating, spray coating, or the like.

The metal solution 5 may be, for example, a solution in which a doped metal precursor and didodecyldimethylammonium bromide (DDAB) are dissolved, for example, a toluene solution. For example, the metal solution 5 may be a solution in which a metal salt containing a doped metal and DDAB are added and dissolved, for example, a toluene solution. Here, as the solvent constituting the metal solution 5, a solvent other than toluene may be used.

For example, about 10 mg of a metal salt and about 80 mg of DDAB may be added to about 10 ml of toluene and dissolved by stirring to prepare the metal solution 5. For example, a metal solution not containing dodecylamine (DDA) may be prepared as a doping solution. In this case, any one of CuCl₂, AgNO₃, AgCl, and AuCl₃ may be used as a metal salt, and other types of metal salt may be used depending on a metal to be doped. Here, the use of toluene as a solvent of the metal solution is illustrated, but embodiments are not limited thereto, and other types of solvents may be used.

After heating the metal solution prepared in this manner to a predetermined temperature, for example, about 60 degrees, QD doping may be performed by soaking the QD array 3 and the entire base portion 1 on which the QD array 3 is formed in the metal solution (S30). The QDs of the QD array 3 may be reacted with the metal solution 5 for a certain time, for example, about 15 minutes. Here, because the QDs of the QD array 3 include the cross-link formed in step S20, a phenomenon in which QDs are melted does not occur even if the metal solution 5 does not contain DDA.

Here, the QD is, for example, about 0.2 nm to about 10 nm in size, so one QD includes about 1,000 to 100,000 atoms. In addition, an atom number density of silicon corresponds to approximately 5*10²²/cm². Therefore, for example, in the case of a QD in which one atom is doped into a particle with a size of 3 to 10 nm, a doping density is 5*10¹⁹/cm²˜5*10¹⁷/cm² based on silicon, which corresponds to a heavy-doping regime. Accordingly, in the case of QDs, physical properties may be significantly changed even if only one atom per particle is doped.

Next, the entire base portion 1, on which the QD array 3 is formed, soaked in the metal solution 5 may be taken out, the QD array 3 may be cleaned with a pure solution, and dried (S40). In FIG. 2D, reference numeral 7 denotes doped QDs that are doped, cleaned, and dried. For the cleaning of the doped QD array, a base solvent of a metal solution used during doping, for example, a pure toluene solution, or another pure solution may be used.

In the above description, about 10 ml of toluene is used to prepare a metal solution 5 to be used for doping, but embodiments are not limited thereto. For example, when using toluene as a solvent, the amount of toluene may vary. In addition, other solvents may be used instead of toluene. In addition, the amount and type of a metal salt, and amount of DDAB added to make a metal solution to be used for doping are shown by way of example, and embodiments are not limited thereto and the amount of the added metal salt and DDAB and the type of the metal salt may be variously changed.

In the manufacturing method according to an embodiment described above, QD doping is performed on the QD array 3 constituting the QD film using the metal solution 5, and thus, doping may be performed on any type of QDs, regardless of QD material, whether a material is dissolved in a solvent, or a type of legend.

For example, in the case of doping the QDs through a reaction in a solution, doping may be performed only on QDs formed of a specific material soluble in a reaction solvent. The method for producing a QD film according to an example embodiment may be universally applied to doping all kinds of QDs.

In addition, in the manufacturing method according to an example embodiment, because an organic ligand such as DDA is not used for QD doping, a problem that arises when an organic ligand such as DDA is used does not arise. That is, in the existing doping method of dispersing QDs in a doping solution to proceed with doping, it is necessary to add excess DDA to cause a doping reaction without precipitation or sedimentation of QDs during a solution reaction, which may overlap an absorbance peak of QDs and cause the excess DDA to remain, without being completely removed from the QDs, after doping. According to an example embodiment, because doping is performed in the state of the QD film, DDA is not required, and thus, the aforementioned problems due to excess DDA do not arise.

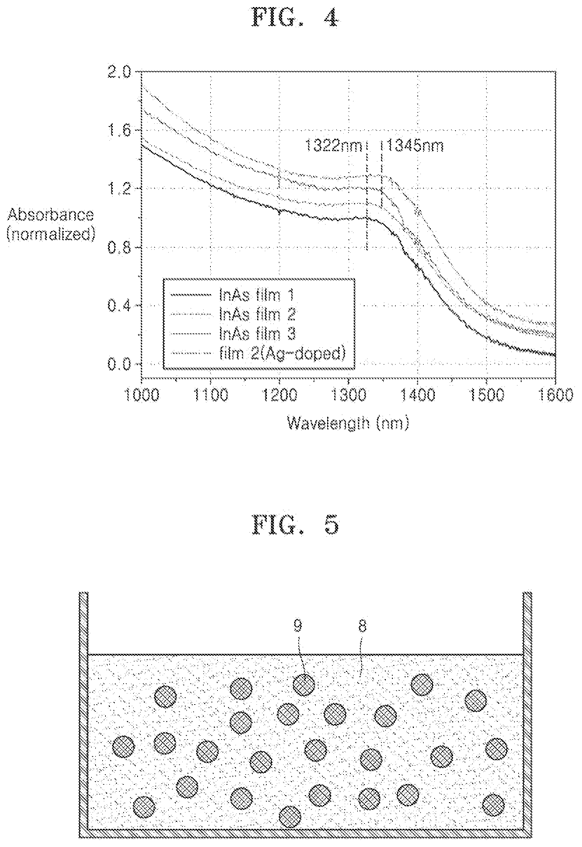

FIG. 4 is a graph showing a shift of absorbance peaks before and after Ag doping of InAS QD films using a method for producing a QD film according to an embodiment. In FIG. 4, a film 1, a film 2, and a film 3 each include InAs QDs.

An absorbance graph of FIG. 4 illustrates that, comparing the absorbance characteristics of an undoped sample of film 2 and an Ag doped sample of film 2, an absorbance peak of the undoped sample is located at approximately 1322 nm and the Ag-doped sample according to the manufacturing method according to an example embodiment has an absorbance peak shifted to 1345 nm. The peak of about 1322 nm before doping is red-shifted by about 23 nm to about 1345 nm after doping. About 23 nm red-shift, although not a relatively large in peak shift, may be considered as a result of heavy p-doping. From the absorbance peak shift, the QDs of the undoped sample of film 2 having intrinsic n-type properties are converted into p-type during Ag doping. In addition, there is no other absorbance peak than the absorbance peak of the QDs for the Ag-doped sample, based on which it is recognized that there is no excess organic peak. That is, from the absorbance graph of the Ag-doped sample, it can be seen that an organic ligand such as DDA do not exist in the QD film.

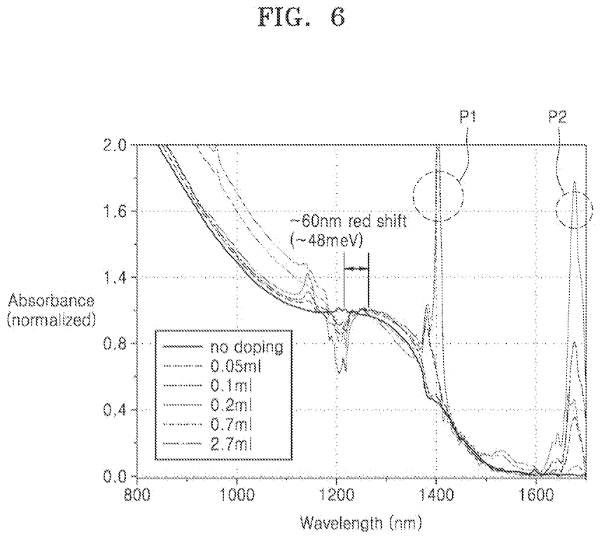

FIG. 5 illustrates a related solution doping method as a comparative example, and FIG. 6 is a graph showing absorbance characteristics when InAs QDs are doped in a toluene solution by applying the related solution doping method.

Referring to FIGS. 5 and 6, the used InAs QDs 9 are QDs having a primary absorbance peak of about 1220 nm. About 10 mg of AgNO₃ (metal salt), about 80 mg of DDAB, and about 120 mg of DDA were added to about 10 ml of toluene and stirred to be dissolved to prepare a metal solution to be doped. The metal solution was added drop-by-drop and stirred to react with 2 ml of toluene InAs QD solution 8. A reaction time was about 15 minutes. FIG. 6 illustrates an absorbance peak shift according to the amount of the added metal salt (AgNO₃) solution.

FIG. 6 illustrates that a red shift of the absorbance peak increases as the amount of added AgNO₃ gradually increases from 0.05 ml to 0.1 ml and 0.2 ml.

Absorbance peaks P1 and P2 increase at about 1400 nm and about 1680 nm, from 0.2 ml of the added AgNO₃ solution. These absorbance peaks are peaks that appear due to DDA added in excess during the reaction, which is not easily removed even when washed off after reacting the QDs with a metal solution for doping. When 2.7 ml of AgNO₃ solution was added, the peak remained visible even after washing, and conversely, the QD absorbance peak undergoes a slight blue shift and changes in shape, from which it may be expected that the QDs themselves are damaged due to a large amount of doping and reactants. That is, during the solution reaction, excess DDA is required to cause a doping reaction without precipitation or sedimentation of QDs, but, in some cases, excess DDA overlaps the absorption peak of the quantum dot or remain without being completely removed from the QDs.

In the method for producing a QD film according to an example embodiment, because DDA is not required due to doping of the QD film state, problems due to excess DDA do not arise.

As described above, in the manufacturing method according to an example embodiment, the QD film including the doped QDs may be formed by performing doping in a state in which the QD array is formed to form a thin film. In this case, the doped QDs of the QD film according to an example embodiment may include cross-links.

Accordingly, the QD film according to an example embodiment may be formed on the surface of the base portion 1, have a QD array 3 including cross-links, and may include doped QDs 7 formed by reacting the QDs with a precursor of a doped metal.

In this case, the QD array 3 may have a single-layer QD array or include a QD stack of two or more layers.

In the QD film according to an example embodiment, the QDs 7 may be, for example, InAs or InSb QDs, and any one of Ag, Au, and Cu may be applied as a doping metal. In addition, the QDs 7 in the QD film according to an example embodiment may be QDs of various materials described above, and various doping metals for p-type or n-type doping may be applied.

In the QD film and the manufacturing method thereof according to an example embodiment, the base portion 1 may correspond to the base portion of the opto-electronic device to which the QD film is applied. For example, when the QD film according to an example embodiment is applied to a field effect transistor (FET)-type opto-electronic device, the base portion 1 may include a stack of first and second semiconductor layers doped opposite to each other.

Most image sensors have an array structure of photodiodes using a silicon process. However, in a near infrared band (about 750 to 2,500 nm), a different material should be used due to a light absorption limit based on bandgap energy of silicon. A QD is a semiconductor material and a wavelength of light absorption varies depending on a size. For example, InAs QDs are easier to absorb than silicon at wavelengths above 1,100 nm and are a material expected to be used without environmental issues in a near-infrared band. When a QD is placed on an image sensor or an optical sensor to form a device, the degree of light absorption may be converted into voltage or current using diode or transistor characteristics of the silicon substrate. In addition, when a 3T or 4T (here, T represents a transistor) circuit is formed on a silicon substrate, a driving circuit suitable for an image sensor may be fabricated.

The QD film according to an example embodiment may be applied to an absorption layer of such an image sensor. For example, by applying the QD film and the method for manufacturing the same according to an example embodiment, an opto-electronic device such as an image sensor having a QD layer as an absorption layer may be implemented.

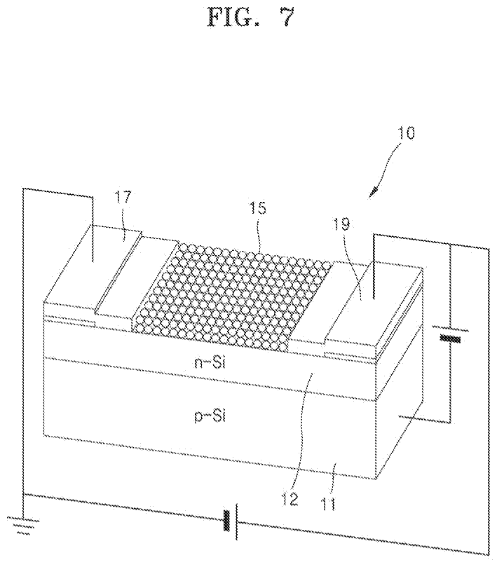

FIG. 7 schematically illustrates a structure of an opto-electronic device 10 according to an example embodiment. FIG. 7 illustrates a QD-Si JFET structure including QDs as an absorption material and silicon (Si) as a material for first semiconductor layer 11 and second semiconductor layer 12, in which the first semiconductor layer 11 may serve as a gate and the second semiconductor layer 12 may correspond to a channel.

Referring to FIG. 7, the opto-electronic device 10 according to an example embodiment includes a base portion, a first electrode 17 and a second electrode 19 formed to be spaced apart from each other on an upper surface of the base portion, and a QD layer 15 positioned between the electrode 17 and the second electrode 19.

In the opto-electronic device 10 according to an example embodiment, the base portion includes the first semiconductor layer 11 doped as a first conductivity type and the second semiconductor layer 12 disposed on an upper surface of the first semiconductor layer 11 and doped as a second conductivity type different from the first conductivity type. In this case, the upper surface of the base portion may correspond to an upper surface of the second semiconductor layer 12, and the first and second electrodes 17 and 19 may each be electrically connected to the second semiconductor layer 12. In addition, the QD layer 15 may be formed to be positioned between the first electrode 17 and the second electrode 19 on the second semiconductor layer 12.

The first semiconductor layer 11 may be formed of, for example, a semiconductor material doped with a p-type. For example, the first semiconductor layer 11 may be formed of silicon (Si) and may be doped with the p-type. The second semiconductor layer 12 may be formed of, for example, a semiconductor material doped with an n-type. For example, the second semiconductor layer 12 may be formed of silicon (Si) and may be doped with the n-type, which is a conductivity type opposite to that of the first semiconductor layer 11. The first semiconductor layer 11 and the second semiconductor layer 12 may be formed of, for example, germanium (Ge) or a compound semiconductor material, and may be electrically doped with opposite conductivity types.

As such, the first semiconductor layer 11 and the second semiconductor layer 12 may be formed of the same type of semiconductor material and may be doped with electrically opposite conductivity types. Accordingly, the first semiconductor layer 11 and the second semiconductor layer 12 may form a pn junction.

As another example, the first semiconductor layer 11 and the second semiconductor layer 12 may be formed of different semiconductor materials and may be electrically doped with opposite conductivity types.

The first and second electrodes 17 and 19 may be formed of, for example, a metal material such as Al, AlN, Ti, TiN, Mo, Pt, Au, Cr, Ni, or Cu. The first and second electrodes 17 and 19 may include various metallic materials used as electrode materials.

The QD layer 15 may be an absorption layer and may be formed on an upper surface of the second semiconductor layer 12 to be positioned between the first and second electrodes 17 and 19. The QD layer 15 may include a cross-link and may include a plurality of doped QDs. The QD layer 15 may include a single-layer QD array, or may have a structure in which QDs are arranged to form a stack of two or more layers.

For the QD layer 15, a material of the QDs, a size of the QDs, etc. may be selected according to a desired absorbance spectrum band.

The QDs of the QD layer 15 may be a nano-size structure formed of a semiconductor (inorganic semiconductor), and may have a diameter of several tens of nm or less, for example, a diameter of about 10 nm or less. For example, the QDs may have a diameter of about 1 nm to about 10 nm.

In addition, the QDs of the QD layer 15 may include, for example, at least one of a group II-VI-based semiconductor, a group III-V-based semiconductor, a group IV-VI-based semiconductor, a group IV-based semiconductor, and graphene QDs. QDs of group II-VI-based semiconductors may include one selected from, for example, a binary compound such as ZnS, ZnSe, ZnTe, CdS, CdSe, CdTe, ZnO, HgS, HgSe, and HgTe, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, and HgZnSe, a quaternary compound such as CdHgZnTe, CdZnSeS, CdZnSeTe, CdZnSTe, CdHgSeS, CdHgSeTe, CdHgSTe, HgZnSeS, HgZnSeTe, and HgZnSTe, and a combination thereof. QDs of group III-V-based semiconductors may include at least one selected from, for example, a binary compound such as GaN, GaP, GaAs, GaSb, AlN, AlP, AlAs, AlSb, InN, InP, InAs, and InSb, a ternary compound such as GaNP, GaNAs, GaNSb, GaPAs, GaPSb, AlNP, AlNAs, AlNSb, AlPAs, AlPSb, InNP, InNAs, InNSb, InPAs, and InPSb, a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, and a combination thereof. QDs of group IV-VI-based semiconductors may include at least one selected from, for example, a binary compound such as SnS, SnSe, SnTe, PbS, PbSe, and PbTe, a ternary compound such as SnSeS, SnSeTe, SnSTe, PbSeS, PbSeTe, PbSTe, SnPbS, SnPbSe, and SnPbTe, a quaternary compound such as SnPbSSe, SnPbSeTe, and SnPbSTe, and a combination thereof. QDs of group IV-based semiconductor may include, for example, Si, Ge, SiGe, SiC, or a combination thereof. Meanwhile, the graphene QDs may be QDs formed of graphene. In addition, QDs may have a core-shell structure having a core portion and a shell portion, or may have a particle structure without a shell (e.g., a core-only structure). The core-shell structure may have a single-shell or a multi-shell. The multi-shell may be, for example, a double-shell. In addition, QDs may include an alloy. An organic ligand or an inorganic ligand may be present on a surface of each QD.

For example, the QD layer 15 may include a plurality of InAs or InSb QDs, and the QDs may include cross-links and may be doped with any one of Ag, Au, and Cu. That is, by forming an intrinsic n-type InAs or InSb QD array, cross-linking and doping the QD array constituting a thin film, the QD layer 15 including a plurality of n-type or p-type QDs may be formed.

The QD layer 15 may be in the form of a thin film including a plurality of QDs, and may be formed by applying the QD film and the manufacturing method thereof described above with reference to FIGS. 1 to 5.

For example, the QDs of the QD layer 15 may include cross-link by a cross-linking process performed using a solution in which a linker such as diamine, dithiol, etc. is dissolved in a solvent such as methanol during a QD film manufacturing process including the QD array. Whether the QDs includes a cross-link may be checked by, for example, a component analysis (inductively coupled plasma (ICP)), X-ray photoelectron spectroscopy (XPS), nuclear magnetic resonance (NMR), gas chromatography (GC) mass-spectrometer, and the like.

The QD layer 15 may include doped QDs by performing doping on the QD array in which cross-linking is completed. Here, because doping is performed on the QDs in which the cross-link is formed, an organic ligand such as DDA is not used for doping, a solvent applied to make a metal solution to be used for doping may be toluene or any other solvents, and the amounts of a metal salt and DDAB being added and the type of the metal salt may be variously changed. In addition, as described above, because QD doping is performed after cross-linking is completed, doping is possible for all types of QDs without limitation on the QD material, whether it is soluble in a solvent, or a ligand type.

Accordingly, a material ora size of the QDs of the QD layer 15 may be selected according to a desired absorbance spectrum band, and may be formed to include doped QDs, including crosslinks.

In the opto-electronic device 10 according to an example embodiment described above with reference to FIG. 7, the QD layer 15 includes a plurality of QDs. The QD layer 15 may be formed of only a plurality of QDs. In addition, the QD layer 15 may further include an oxide layer on at least one side thereof. For example, in the QD layer 15, QDs may be arranged to be in contact with the upper surface of the base portion, e.g., the upper surface of the second semiconductor layer 12, and the oxide layer may be provided to cover the QDs. As another example, in the QD layer 15, a plurality of QDs may be in contact with the upper surface of the QD layer 15, and an oxide layer may be provided to be positioned between the QDs and the upper surface of the base portion, that is, the upper surface of the second semiconductor layer 12. As another example, the QD layer 15 may be provided in a form in which a plurality of QDs may be surrounded by an oxide layer. For example, an oxide layer may be positioned between the plurality of QDs and the upper surface of the base portion, that is, the upper surface of the second semiconductor layer 12, and an oxide layer may also be positioned at an upper end of the QD layer 15.

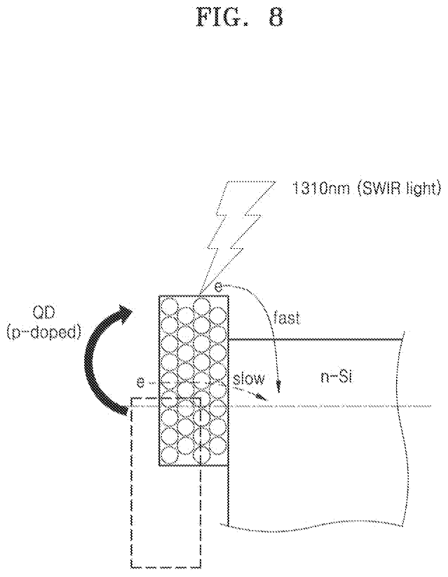

FIG. 8 illustrates a difference in reaction rate according to whether QDs are doped in an opto-electronic device having a QD-Si JFET structure. In FIG. 8, the solid line box indicates a QD layer including p-doped InAs QDs (Example as an embodiment), and the dotted line box indicates a QD layer including undoped InAs QDs (Related Example). An n-Si layer corresponds to the second semiconductor layer 12 in the opto-electronic device 10 of FIG. 7.

Referring to FIG. 8, the QD layer of Related Example includes undoped InAs QDs, and thus exhibits intrinsic n-type characteristics. In contrast, the QD layer of Example includes p-doped InAs QDs, and thus exhibits p-type characteristics.

When SWIR light having a wavelength of about 1310 nm is incident on the QD layer of Related Example and the QD layer of Example, photoelectrons (e-) generated by absorbing light are moved to the n-Si layer. Here, the photoelectrons (e-) generated in the QD layer of Example are rapidly moved to the n-Si layer, whereas the photoelectrons (e-) generated in the QD layer of Related Example are slowly moved to the n-Si layer.

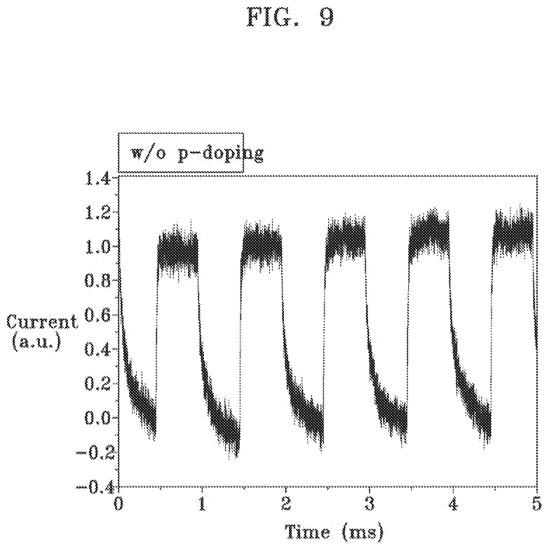

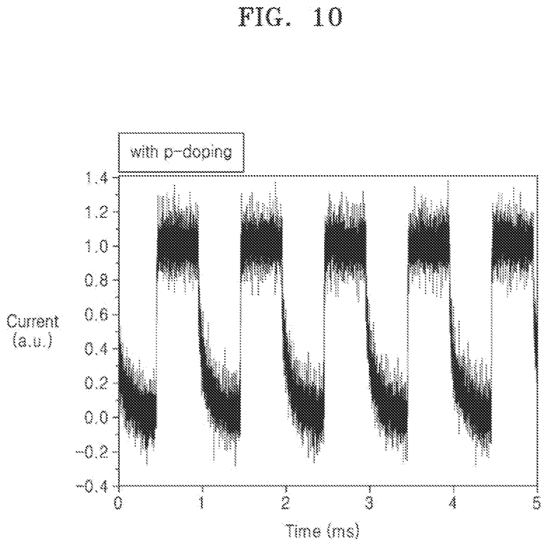

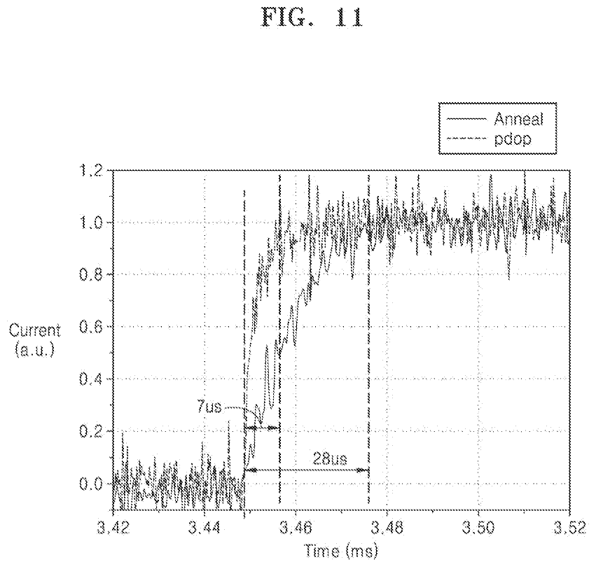

FIGS. 9 and 10 illustrate changes in the photocurrent detected in a sample of Related Example and a sample of Example of FIG. 8, and FIG. 11 illustrates a difference in rise time of photocurrent detected in the sample of Related Example and the sample of Example. FIGS. 9 to 10 illustrate photocurrent detection characteristics when SWIR light having a wavelength of about 1310 nm and optically switched by about 1 kHz is incident on a device having a channel length of about 3 μm.

Referring to FIGS. 9 to 11, it can be seen that a rise time of the detected photocurrent in the sample of Related Example in which QDs are not doped is slow as about 28 μs, whereas a rise time of the sample of Example including the doped QDs is fast as about 7 μs.

In the above, it has been described and illustrated for an example that the QD film according to an example embodiment is applied to the opto-electronic device having a QD-Si JFET structure with reference to FIGS. 7 to 11, but a material of the QDs, a material of the semiconductor layer of the JFET structure, a structure of the JFET structure may be variously changed.

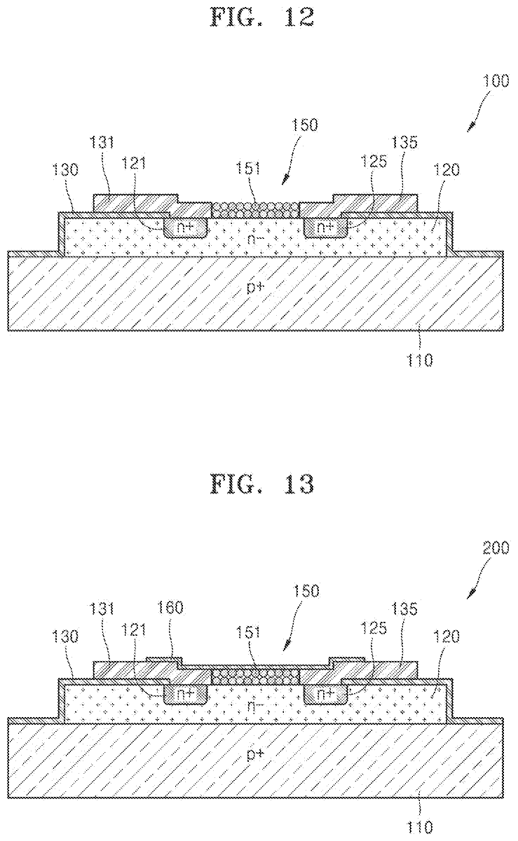

FIGS. 12 to 15 are cross-sectional views schematically illustrating a structure of an opto-electronic device 100 according to various example embodiments.

FIG. 12 is a cross-sectional view schematically showing a structure of the opto-electronic device 100 according to an example embodiment.

Referring to FIG. 12, the opto-electronic device 100 according to an example embodiment includes a base portion, a first electrode 131 and a second electrode135 formed to be spaced apart from each other on an upper surface of the base portion, and a QD layer 150 positioned between the electrode 131 and the second electrode 135 on the base portion.

In the opto-electronic device 100 according to an example embodiment, the base portion includes a first semiconductdor layer 110 doped as a first conductivity type and a second semiconductor layer 120 disposed on an upper surface of the first semiconductor layer 110 and doped as a second conductivity type different from the first conductivity type. In this case, an upper surface of the base portion may correspond to an upper surface of the second semiconductor layer 120, and the first and second electrodes 131 and 135 may each be electrically connected to the second semiconductor layer 120. In addition, the QD layer 150 may be formed on the second semiconductor layer 120 to be positioned between the first electrode 131 and the second electrode 135. In addition, a first doped region 121 and a second doped region 125 positioned to be spaced apart from each other in the second semiconductor layer 120 and doped with a concentration different from the second semiconductor layer 120, and the first and second electrodes 131 and 135 may be electrically connected to the first and second doped regions 121 and 125, respectively. Any one of the first and second doped regions 121 and 125 may be a source region and the other may be a drain region, and an electrode electrically connected to the source region, among the first and second electrodes 131 and 135, may be a source electrode and an electrode electrically connected to the drain region may be a drain electrode.

The first semiconductor layer 110 may be formed of, for example, a semiconductor material doped with a high concentration of p+ type. For example, the first semiconductor layer 110 may be formed of silicon (Si), germanium (Ge), or a compound semiconductor material, and may be doped with a p+ type.

The second semiconductor layer 120 may be formed of, for example, an n-type doped semiconductor material. For example, the second semiconductor layer 120 may be formed of a semiconductor material and may be doped with an n-type having a conductivity opposite to that of the first semiconductor layer 110 at a lower concentration than that of the first semiconductor layer 110. The second semiconductor layer 120 may be formed of the same type of semiconductor material as the first semiconductor layer 110 and may be doped with a conductivity type that is electrically opposite to that of the first semiconductor layer 110. Accordingly, the first semiconductor layer 110 and the second semiconductor layer 120 may form a p-n junction.

In the example embodiment, the second semiconductor layer 120 may be formed on the first semiconductor layer 110 to form a step with the first semiconductor layer 110. For example, the second semiconductor layer 120 may be formed to be positioned only on a partial region of the first semiconductor layer 110 to form a step with the first semiconductor layer 110. For example, the first semiconductor layer 110 and the second semiconductor layer 120 may be formed on a substrate, for example, a semiconductor substrate, through a doping process or a deposition process, and in this case, a region corresponding to the second semiconductor layer may be patterned so that the second semiconductor layer 120 is positioned only on the partial region of the first semiconductor layer 110, so that the second semiconductor layer 120 is stepped for the first semiconductor layer 110. As another example, a region corresponding to the first semiconductor layer 110 in a semiconductor substrate may be doped to form the first semiconductor layer 110, and the second semiconductor layer 120 may be deposited and formed on a partial region of the first semiconductor layer 110.

The first and second doped regions 121 and 125 may be doped with a concentration different from that of the second semiconductor layer 120 to be spaced apart from each other in the second semiconductor layer 120. For example, the first and second doped regions 121 and 125 may be formed by doping a partial region of the second semiconductor layer 120 as n+-type.

The first and second electrodes 131 and 135 may be formed to be electrically connected to the first and second doped regions 121 and 125, respectively. The first and second electrodes 131 and 135 may be formed of, for example, a metal material such as Al, AlN, Ti, TiN, Mo, Pt, Au, Cr, Ni, or Cu. The first and second electrodes 131 and 135 may include various metallic materials used as electrode materials.

In the example embodiment, the first and second electrodes 131 and 135 may be formed to extend to an upper surface of the second semiconductor layer 120 between the first and second doped regions 121 and 125 so that the QD layer 150 is not directly electrically connected to the first and second doped regions 121 and

In this manner, when the first and second electrodes 131 and 135 are formed so that the QD layer 150 is not directly electrically connected to the first and second doped regions 121 and 125, photocarriers generated by light absorption in the QD layer 150 may not be transferred directly to the first and second doped regions 121 and 125, but may be transferred through the second semiconductor layer 120 constituting a channel.

An insulating layer 130 may be further formed over the first semiconductor layer 110 and the second semiconductor layer 120. The insulating layer 130 may be formed to extend from a step portion between the first semiconductor layer 110 and the second semiconductor layer 120 and to the first and second doped regions 121 and 125 on the second semiconductor layer 120, and the first and second electrodes 131 and 135 may be electrically connected to the first and second doped regions 121 and 125 and positioned on the insulating layer 130. The insulating layer 130 may be formed of, for example, any one of SiO₂, Si₃N₄, Al₂O₃, and HfO₂.

As described above, when the insulating layer 130 is further provided over the first semiconductor layer 110 and the second semiconductor layer 120, the first electrode 131 and the second electrode 135 may be formed to have a step structure due to the presence of the insulating layer 130.

As such, the first and second electrodes 131 and 135 may be spaced apart from each other so as to be electrically connected to the first and second doped regions 121 and 125 on the upper surface of the base portion and may be formed in a step structure.

The QD layer 150 may be an absorption layer and may be formed on the upper surface of the second semiconductor layer 120 between the first and second electrodes 131 and 135. The QD layer 150 may include a cross-link, may include a plurality of doped QDs, and may be formed in a thin film form. The QD layer 150 may include a single-layer QD array or may have a structure in which QDs are arranged to form a stack of two or more layers. In the QD layer 150, a material of QDs, a QD size, etc. may be selected according to a desired absorbance spectrum band, and the QD layer 150 may be formed to include doped QDs, including crosslinks. The QDs of the QD layer 150 may have a nano-size structure formed of a semiconductor (inorganic semiconductor), and may have a diameter of several tens of nm or less, for example, a diameter of about 10 nm or less. For example, the QDs may have a diameter of about 1 nm to about 10 nm. In addition, the QDs of the QD layer 150 may include, for example, at least one of group II-VI-based semiconductors, group III-V-based semiconductors, group IV-VI-based semiconductors, group IV-based semiconductors, and graphene QDs. Here, material types of the QDs of the group II-VI-based semiconductors, the QDs of the group III-V-based semiconductors, the QDs of the group IV-VI-based semiconductors, and the QDs of the group IV-based semiconductors are the same as those described above for the material types of the QDs of the QD layer 15 with reference to FIG. 7, and thus, a repeated description thereof here is omitted. The graphene QDs may be QDs formed of graphene. In addition, the QD may have a core-shell structure having a core portion and a shell portion, or may have a particle structure without a shell (e.g., a core-only structure). The core-shell structure may have a single-shell or a multi-shell. A multi-shell may be, for example, a double-shell. In addition, the QDs may include an alloy. An organic ligand or an inorganic ligand may be present on the surface of the QD.

The QD layer 150 is in the form of a thin film including a plurality of QDs, and may be formed by applying the QD film and manufacturing method thereof described above with reference to FIGS. 1 to 5.

That is, the QDs of the QD layer 150 may include cross-links by a cross-linking process performed using a solution in which a linker such as diamine, dithiol, etc. is dissolved in a solvent such as methanol during a process of producing a QD film including a QD array. Whether the QDs includes a cross-link may be checked by, for example, a component analysis (ICP), XPS, NMR, GC mass-spectrometer, and the like.

The QD layer 150 may include a plurality of doped QDs by performing doping on the QD array on which cross-linking is completed. Here, because doping is performed on the QDs in which the cross-link is formed, an organic ligand such as DDA is not used for doping, a solvent applied to make a metal solution to be used for doping may be toluene or any other solvents, and the amounts of a metal salt and DDAB being added and the type of the metal salt may be variously changed. In addition, as described above, because QD doping is performed after cross-linking is completed, doping is possible for all types of QDs without limitation on the QD material, whether it is soluble in a solvent, or a ligand type.

Accordingly, a material or a size of the QDs of the QD layer 150 may be selected according to a desired absorbance spectrum band, and may be formed to include doped QDs, including crosslinks.

FIG. 13 is a cross-sectional view schematically illustrating a structure of an opto-electronic device 200 according to another example embodiment. The example embodiment of FIG. 13 is different from the embodiment of FIG. 12 in that a protective layer 160 is further provided on the uppermost portion of a light receiving region. The protective layer 160 may be formed over the QD layer 150 and the first and second electrodes 131 and 135. The protective layer 160 may protect the QD layer 150 more stably by preventing penetration of oxygen (O₂), moisture (H₂O), foreign matter, and the like. The protective layer 160 may be formed of, for example, any one of Al₂O₃, HfO₂, and ZrO₂ insulator materials. The protective layer 160 may be formed by, for example, an atomic layer deposition (ALD) method. The protective layer 160 may be formed of a material such as SiO₂.

The opto-electronic devices 100 and 200 according to the example embodiments shown in FIGS. 12 and 13 may be formed by applying, for example, an n-channel epi-wafer on a p+ substrate.

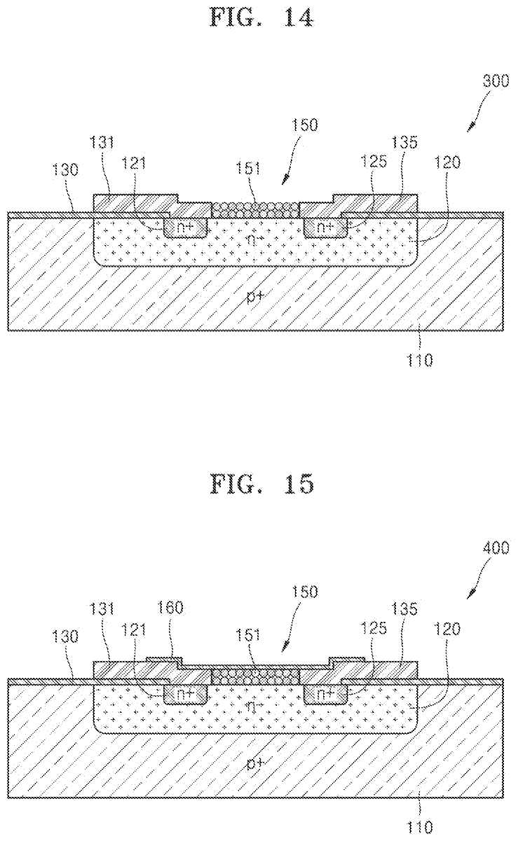

FIG. 14 is a cross-sectional view schematically illustrating a structure of an opto-electronic device 300 according to another example embodiment. The example embodiment of FIG. 14 is different from the embodiment of FIG. 12 in that the second semiconductor layer 120 is formed in a partial region of the first semiconductor layer 110 by doping with a second conductive type, instead of forming the second semiconductor layer 120 to form a step with the first semiconductor layer 110.

FIG. 15 is a cross-sectional view schematically illustrating a structure of an opto-electronic device 400 according to another example embodiment. The example embodiment of FIG. 15 is different from the example embodiment of FIG. 14 in that the protective layer 160 is further provided on the uppermost portion of the light receiving region. The protective layer 160 may be formed over the QD layer 150 and the first and second electrodes 131 and 135. The protective layer 160 is to prevent penetration of oxygen (O₂), moisture (H₂O), foreign matter, etc., and may be formed of, for example, any one of Al₂O₃, HfO₂, and ZrO₂.

Referring to FIGS. 14 and 15, the first and second semiconductor layers 110 and 120 may be formed so that uppermost surfaces thereof are positioned at the same height.

As described above, when the second semiconductor layer 120 is formed in a partial region of the first semiconductor layer 110 doped with the first conductivity type by doping with the opposite second conductivity type, the first and second doped regions 121 and 125 may be spaced apart from each other in the second semiconductor layer 120 and doped with a doping concentration different from that of the second semiconductor layer 120.

In addition, the first electrode 131 and the second electrode 135 may be electrically connected to the first and second doped regions 121 and 125 and extend to an upper surface of the second semiconductor layer 120 in a region between the first and second doped regions 121 and 125 so that the QD layer 150 is not directly electrically connected to the first and second doped regions 121 and 125. In this case, photocarriers generated according to light absorption in the QD layer 150 may not be directly transferred to the first and second doped regions 121 and 125, but may be transferred through the second semiconductor layer 120 constituting a channel.

As in FIGS. 14 and 15, even when the first and second semiconductor layers 110 and 120 are formed so that the uppermost end surfaces are located at the same level, the insulating layer 130 extending to the first and second doped region 121 and 125 on the upper surface of the first semiconductor layer 110 and the upper surface of the second semiconductor layer 120 may be further provided. In this case, the first and second electrodes 131 and 135 may be formed on the insulating layer 130 to be electrically connected to the first and second doped regions 121 and 125, respectively.

As described above, when the insulating layer 130 is further provided on the first semiconductor layer 110 and the second semiconductor layer 120, the first electrode 131 and the second electrode 135 may form a step structure due to the presence of the insulating layer 130.

In the opto-electronic devices 100, 200, 300, and 400 of FIGS. 12 to 15, the base portion is formed to have a pn junction of the first semiconductor layer 110 doped with the first conductivity type and the second semiconductor layer 120 doped with the second conductivity type, thereby having a structure of a JFET. In this case, the first semiconductor layer 110 may serve as a gate, and the second semiconductor layer 120 may correspond to a channel.

In the opto-electronic devices 100, 200, 300, and 400 according to the example embodiments of FIGS. 12 to 15, when the first semiconductor layer 110 serving as a gate is doped with p+ type, for example, and the second semiconductor layer 120 serving as a channel is doped with n-type, for example, current flows between the first doped region 121 and the second doped region 125 through the second semiconductor layer 120, while a gate voltage is not applied to the first semiconductor layer 110. However, when a reverse voltage, that is, a negative voltage, is applied to the first semiconductor layer 110, a depletion region in the second semiconductor layer 120 is widened and the current flowing between the first doped region 121 and the second doped region 125 is reduced. In addition, when a reverse voltage equal to or greater than a certain strength is applied to the first semiconductor layer 110, the second semiconductor layer 120 is filled with a depletion region and no current flows between the first doped region 121 and the second doped region 125. Accordingly, the opto-electronic devices 100, 200, 300, and 400 may be in an ON state when no voltage is applied to the first semiconductor layer 110, and may be in an OFF state when a reverse voltage greater than or equal to a threshold voltage is applied to the first semiconductor layer 110.

In the opto-electronic devices 100, 200, 300, and 400 according to various example embodiments of FIGS. 12 to 15, the QD layer 150, as an absorption layer that absorbs incident light and photoelectrically converts light, is positioned between the first and second electrodes 131 and 135 on the upper surface of the base portion. That is, the QD layer 150 is positioned between the first and second electrodes 131 and 135 on the upper surface of the second semiconductor layer 120 of the base portion.

In the opto-electronic devices 100, 200, 300, and 400 according to various example embodiments of FIGS. 12 to 15, the QD layer 150 includes a plurality of QDs 151. The QD layer 150 may be formed of only a plurality of QDs 151. In addition, the QD layer 150 may further include an oxide layer on at least one side thereof. For example, in the QD layer 150, the plurality of QDs 151 may be arranged to be in contact with the upper surface of the base portion, e.g., the upper surface of the second semiconductor layer 120, and the oxide layer may be provided to cover the QDs 151. As another example, in the QD layer 150, the plurality of QDs 151 may be in contact with the upper surface of the QD layer 150, and an oxide layer may be provided to be positioned between the plurality of QDs 151 and the upper surface of the base portion, that is, the upper surface of the second semiconductor layer 120. As another example, in the QD layer 150, the plurality of QDs 151 may be surrounded by an oxide layer. For example, an oxide layer may be positioned between the plurality of QDs 151 and the upper surface of the base portion, that is, the upper surface of the second semiconductor layer 120, and an oxide layer may also be positioned at an upper end of the QD layer 150.

Because the opto-electronic devices 10, 100, 200, 300, and 400 according to an example embodiment as described above include the QD layer 150, dark noise may be reduced, and more photocarriers than photons incident on the opto-electronic devices 10, 100, 200, 300, and 400 per unit time are generated using the plurality of QDs 151, obtaining a gain greater than 1, thereby improving light reception efficiency.

The opto-electronic devices 10, 100, 200, 300, and 400 above described may be used alone as light receiving devices or may be arranged in a two-dimensional array to constitute an image sensor.

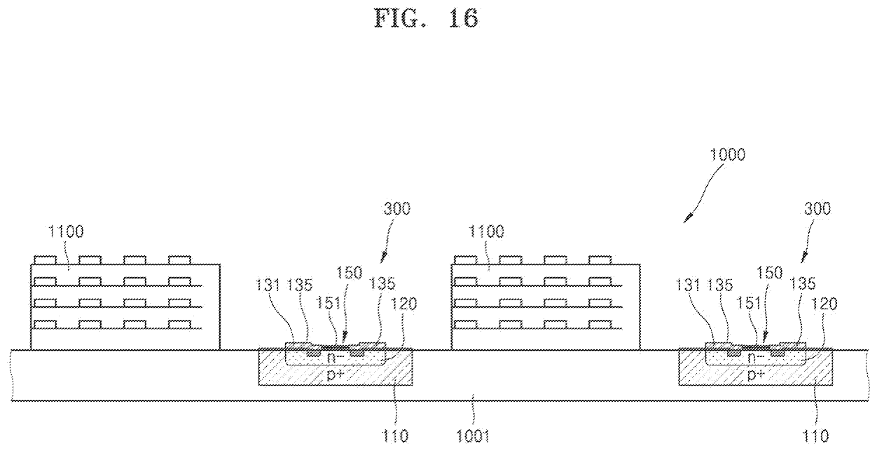

FIG. 16 is a cross-sectional view schematically illustrating a structure of an image sensor 1000 to which at least one of opto-electronic devices 10, 100, 200, 300, and 400 according to the example embodiments is applied as a plurality of opto-electronic devices. FIG. 16 exemplarily illustrates a case in which the opto-electronic device 300 described above with reference to FIG. 14 is applied to the image sensor 1000. At least one of the opto-electronic devices 10, 100, 200, 300, and 400 of the various embodiments described above may be applied to the image sensor 1000.

Referring to FIG. 16, the image sensor 1000 may include an array of a plurality of opto-electronic devices 300 formed on a substrate 1001 and a plurality of driving circuits 1100 for outputting signals from each of the plurality of opto-electronic devices 300, and the array of the plurality of opto-electronic devices 300 may be two-dimensionally arranged along a plurality of rows and columns to form a pixel array. Although only two opto-electronic devices 300 and two driving circuits 1100 are shown in FIG. 16 for convenience, a very large number of opto-electronic devices and driving circuit elements may be arranged in the form of a 2D array.

The image sensor 1000 may further include, for example, a timing controller, a row decoder, and an output circuit. The image sensor 1000 may be a charge coupled device (CCD) image sensor or a complementary metal oxide semiconductor (CMOS) image sensor.

The opto-electronic devices constituting the pixel array may be two-dimensionally arranged in a plurality of rows and columns. Each opto-electronic device may correspond to a pixel. The row decoder selects one of the rows of the pixel array in response to a row address signal output from the timing controller. The output circuit outputs a light detection signal from a plurality of pixels arranged in a selected row in a column unit. To this end, the output circuit may include a column decoder and an analog-to-digital converter (ADC). For example, the output circuit may include a plurality of ADCs respectively disposed for each column between the column decoder and the pixel array, or one ADC disposed at an output terminal of the column decoder. The timing controller, the row decoder, and the output circuit may be implemented as one chip or as separate chips. A processor for processing an image signal output through the output circuit may be implemented as a single chip together with the timing controller, the row decoder, and the output circuit.

The opto-electronic devices 10,100, 200, 300, and 400 described above have low dark noise and high sensitivity by applying QDs doped with an absorption material, and thus, the image sensor 1000 to which the opto-electronic devices 10, 100, 200, 300, and 400 are applied as a light detecting element of each pixel may obtain a clear image even with weak incident light. In addition, because it is possible to further reduce a size of the pixels of the image sensor 1000, the resolution of the image sensor may be further increased. The image sensor 1000 may be implemented as, for example, a CMOS image sensor.

In addition, by changing the size of the plurality of QDs to correspond to a wavelength range to be detected in the opto-electronic devices 10, 100, 200, 300, and 400 described above, an image sensor or a QD image sensor may be implemented, or various optical sensors such as an optical device that detects light in a desired wavelength range, an infrared sensor, or an infrared image sensor may be implemented.

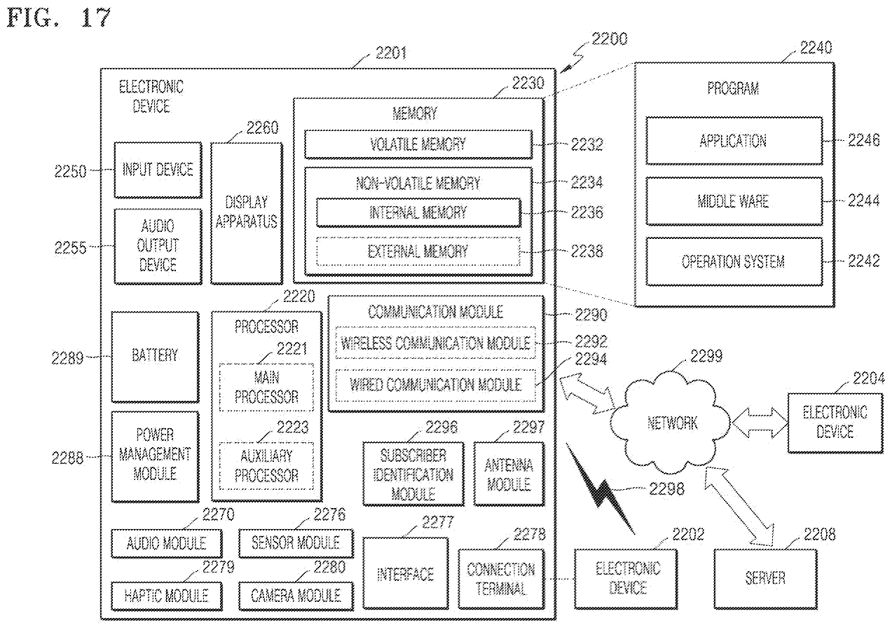

FIG. 17 is a block diagram illustrating a schematic structure of an electronic device 2201 including an image sensor according to an example embodiment.

Referring to FIG. 17, in a network environment 2200, the electronic device 2201 may communicate with another electronic device 2202 through a first network 2298 (a short-range wireless communication network, etc.) or communicate with another electronic device 2204 and/or a server 2208 through a second network 2299 (a long-range wireless communication network, etc.). The electronic device 2201 may communicate with the electronic device 2204 through the server 2208. The electronic device 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. Some of these components of the electronic device 2201 may be omitted or other components may be added to the electronic device 2201. Some of these components may be implemented as one integrated circuit. For example, a fingerprint sensor, an iris sensor, an illuminance sensor, etc. of the sensor module 2210 may be implemented to be embedded in the display device 2260 (display, etc.).

The processor 2220 may execute software (a program 2240, etc.) to control one or a plurality of other components (hardware, software components, etc.)

among electronic devices 2201 connected to the processor 2220 and perform various data processing or operations As part of the data processing or operations, the processor 2220 may load instructions and/or data received from other components (the sensor module 2210, the communication module 2290, etc.) into a volatile memory 2232, process instructions and/or data stored in the volatile memory 2232, and store result data in a nonvolatile memory 2234. The processor 2220 may include a main processor 2221 (a central processing unit, an application processor, etc.) and an auxiliary processor 2223 (a graphics processing unit, an image signal processor, a sensor hub processor, a communication processor, etc.) that may be operated independently or together with the main processor 2221. The auxiliary processor 2223 may use less power than the main processor 2221 and may perform specialized functions.

The auxiliary processor 2223 may control functions and/or states related to some (the display apparatus 2260, the sensor module 2210, the communication module 2290, etc.) of the components of the electronic device 2201 in place of the main processor 2221 while the main processor 2221 is inactive (a sleep state) or together with the main processor 2221 while the main processor 2221 is active (an application executed state). The auxiliary processor 2223 (an image signal processor, a communication processor, etc.) may be implemented as part of other functionally related components (the camera module 2280, the communication module 2290, etc.).

The memory 2230 may store various data required by the components (the processor 2220, the sensor module 2210, etc.) of the electronic device 2201. The data may include, for example, software (the program 2240, etc.) and input data and/or output data for commands related thereto. The memory 2230 may include the volatile memory 2232 and/or the nonvolatile memory 2234.

The program 2240 may be stored as software in the memory 2230 and may include an operating system 2242, middleware 2244, and/or an application 2246.

The input device 2250 may receive commands and/or data to be used by components (the processor 2220, etc. of the electronic device 2201) from the outside (a user, etc.) of the electronic device 2201. The input device 2250 may include a microphone, a mouse, a keyboard, and/or a digital pen (such as a stylus pen).

The audio output device 2255 may output an audio signal to the outside of the electronic device 2201. The audio output device 2255 may include a speaker and/or a receiver. The speaker may be used for general purposes such as multimedia playback or recording playback, and the receiver may be used to receive incoming calls. The receiver may be combined as part of the speaker or may be implemented as an independent separate device.

The display device 2260 may visually provide information to the outside of the electronic device 2201. The display device 2260 may include a control circuit for controlling a display, a hologram device, or a projector and a corresponding device. The display device 2260 may include a touch circuitry configured to detect a touch and/or a sensor circuitry (a pressure sensor) configured to measure the intensity of force generated by a touch. The display device 2260 may include any one of the display devices described above or a display device having a structure modified therefrom. A plurality of display devices 2260 may be provided.

The audio module 2270 may convert sound into an electrical signal, or conversely, may convert an electrical signal into sound. The audio module 2270 may acquire sound through the input device 2250 and output sound through a speaker and/or a headphone of another electronic device (the electronic device 2202, etc.) connected to the audio output device 2255 and/or the electronic device 2201 directly or wirelessly.

The sensor module 2210 may detect an operating state (power, temperature, etc.) of the electronic device 2201 or an external environmental state (a user state, etc.), and generate an electrical signal and/or data value corresponding to the detected state. The sensor module 2210 may include a fingerprint sensor, an acceleration sensor, a position sensor, a 3D sensor, etc. and, in addition to this, the sensor module 2210 may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illuminance sensor.

The interface 2277 may support one or more designated protocols that may be used for the electronic device 2201 to be connected to another electronic device (e.g., the electronic device 2202) directly or wirelessly. The interface 2277 may include a high definition multimedia interface (HDMI), a universal serial bus (USB) interface, an SD card interface, and/or an audio interface.

A connection terminal 2278 may include a connector through which the electronic device 2201 may be physically connected to another electronic device (such as the electronic device 2202). The connection terminal 2278 may include an HDMI connector, a USB connector, an SD card connector, and/or an audio connector (such as a headphone connector).

The haptic module 2279 may convert an electrical signal into a mechanical stimulus (vibration, movement, etc.) or an electrical stimulus that a user may perceive through a tactile or motor sense. The haptic module 2279 may include a motor, a piezoelectric element, and/or an electrical stimulation device.

The camera module 2280 may capture a still image and video. The camera module 2280 may include a lens assembly including one or more lenses, image sensors, image signal processors, and/or flashes. The camera module 2280 may have the image sensor 1000 described above or a structure modified therefrom, and pixels of the image sensor 1000 may have a structure of any one of the opto-electronic devices 10, 100, 200, 300, and 400 described above or a combination thereof or a modified structure thereof. A plurality of camera modules 2280 operating in various wavelength bands may be provided.

The application 2246 may include one or more applications executed in connection with the display device 2260. Such an application may display additional information suitable for a user environment on the display device 2260. For example, the camera module 2280 may be utilized as a sensor for recognizing a user environment, and additional information necessary according to the recognized result may be displayed on the display device 2260.

The power management module 2288 may manage power supplied to the electronic device 2201. The power management module 2288 may be implemented as part of a power management integrated circuit (PMIC).

The battery 2289 may supply power to components of the electronic device 2201. The battery 2289 may include a non-rechargeable primary cell, a rechargeable secondary cell, and/or a fuel cell.

The communication module 2290 may establish a direct (wired) communication channel and/or a wireless communication channel between the electronic device 2201 and other electronic devices (the electronic device 2202, the electronic device 2204, the server 2208, etc.) and support communication through the established communication channel. The communication module 2290 may include one or more communication processors operating independently of the processor 2220 (an application processor, etc.) and supporting direct communication and/or wireless communication. The communication module 2290 may include a wireless communication module 2292 (a cellular communication module, a short-range wireless communication module, a global navigation satellite system (GNSS) communication module, etc.) and/or a wired communication module 2294 (a local area network (LAN) communication module, a power line communication module, etc.). Among these communication modules, a corresponding communication module may communicate with another electronic device through the first network 2298 (a short-range communication network such as Bluetooth, WiFi Direct, or infrared Data Association (IrDA) or the second network 2299 (a telecommunication network such as a cellular network, the Internet, or a computer network (LAN, WAN, etc.). These various types of communication modules may be integrated into one component (a single chip, etc.) or may be implemented as a plurality of components (multiple chips) separate from each other. The wireless communication module 2292 may verify and authenticate the electronic device 2201 in the communication network such as the first network 2298 and/or the second network 2299 using subscriber information (an international mobile subscriber identifier (IMSI), etc.) stored in the subscriber identification module 2296.

The antenna module 2297 may transmit signals and/or power to the outside (such as other electronic devices) or receive signals and/or power from the outside. The antenna may include a radiator including a conductive pattern formed on a board (a printed circuit board (PCB), etc.). The antenna module 2297 may include one or a plurality of antennas. When a plurality of antennas are included, an antenna suitable for a communication method used in a communication network such as the first network 2298 and/or the second network 2299 may be selected from among the plurality of antennas by the communication module 2290. Signals and/or power may be transmitted or received between the communication module 2290 and other electronic devices through the selected antenna. A component (an RFIC, etc.) other than the antenna may be included as part of the antenna module 2297.

Some of the components may be connected to each other through communication methods (a bus, a general purpose input and output (GPIO), a serial peripheral interface (SPI), a mobile industry processor interface (MIPI)) and exchange signals (commands, data, etc.) with each other.

The command or data may be transmitted or received between the electronic device 2201 and the electronic device 2204 through the server 2208 connected to the second network 2299. The other electronic devices 2202 and 2204 may be the same or different types of devices as the electronic device 2201. All or some of the operations executed by the electronic device 2201 may be executed by one or more of the other electronic devices 2202, 2204, and 2208. For example, when the electronic device 2201 needs to perform a function or service, the electronic device 2201 may request one or more other electronic devices to perform a portion or the entirety of the function or the service, instead of executing the function or service by itself. Upon receiving the request, one or more other electronic devices may execute an additional function or service related to the request, and transmit a result of the execution to the electronic device 2201. To this end, cloud computing, distributed computing, and/or client-server computing technology may be used.

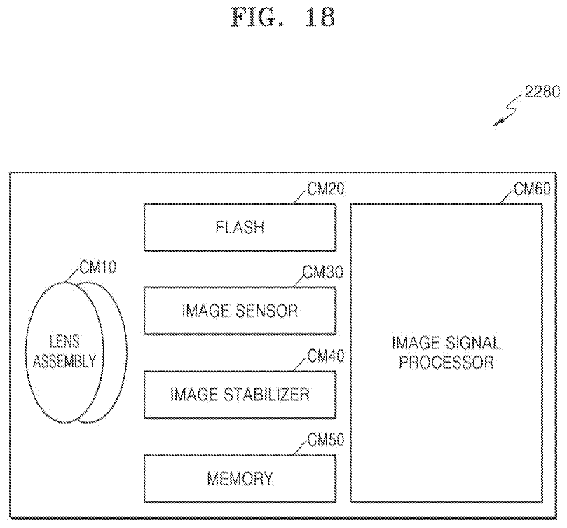

FIG. 18 is a block diagram illustrating a schematic structure of the camera module 2280 included in the electronic device 2201 of FIG. 17.

Referring to FIG. 18, the camera module 2280 may include a lens assembly CM10, a flash CM20, an image sensor CM30, an image stabilizer CM40, a memory CM50 (buffer memory, etc.), and/or an image signal processor CM60.

The image sensor CM30 may include a sensor utilizing the opto-electronic devices 10, 100, 200, 300, and 400 described above. The image sensor CM30 may be implemented as an RGB sensor together with a color filter, a black and white (BW) sensor, or may be implemented as an IR sensor or a UV sensor, or may further include one or a plurality of sensors selected from among image sensors having different properties. Each of the sensors included in the image sensor CM30 may be implemented as a CCD sensor and/or a CMOS sensor, in addition to a sensor utilizing the opto-electronic devices 10, 100, 200, 300, and 400 described above.

The lens assembly CM10 may collect light emitted from a subject, which is an image capturing target. The camera module 2280 may include a plurality of lens assemblies CM10, and in this case, the camera module 2280 may be a dual camera, a 360-degree camera, or a spherical camera. Some of the plurality of lens assemblies CM10 may have the same lens properties (an angle of view, a focal length, auto focusing, F number, optical zoom, etc.) or may have different lens properties. The lens assembly CM10 may include a wide-angle lens or a telephoto lens.

The flash CM20 may emit light used to enhance light emitted or reflected from the subject. The flash CM20 may include one or a plurality of light emitting diodes (red-green-blue (RGB) LEDs, a white LED, an infrared LED, an ultraviolet LED, etc.), and/or a xenon lamp. The flash CM20 may provide light suitable for an operating wavelength band of the image sensor CM30. For example, the flash CM20 may provide visible light, near-infrared light, or light in an infrared band.

In response to a movement of the camera module 2280 or the electronic device 2201 including the camera module 2280, the image stabilizer CM40 may move one or a plurality of lenses included in the lens assembly CM10 or the image sensor 1000 in a certain direction or control operating characteristics (adjustment of a read-out timing, etc.) of the image sensor 1000, thereby compensating for a negative influence due to the movement. The image stabilizer CM40 may detect a movement of the camera module 2280 or the electronic device using a gyro sensor or an acceleration sensor disposed inside or outside the camera module 2280. The image stabilizer CM40 may be implemented optically.

The memory CM50 may store some or all data of an image acquired through the image sensor 1000 for a next image processing operation. For example, when a plurality of images are acquired at high speed, the acquired original data (Bayer-patterned data, high-resolution data, etc.) may be stored in the memory CM50, only a low-resolution image may be displayed, and original data of a selected image (a user selection, etc.) may be transferred to the image signal processor CM60. The memory CM50 may be integrated into the memory 2230 of the electronic device 2201 or may be configured as a separate memory operated independently.

The image signal processor CM60 may perform image processing on an image acquired through the image sensor CM30 or image data stored in the memory CM50.

In addition, image processing may include depth map generation, 3D modeling, panorama generation, feature point extraction, image synthesis, and/or image compensation (noise reduction, resolution adjustment, brightness adjustment, blurring, sharpening, softening, etc.). The image signal processor CM60 may perform control (exposure time control, readout timing control, etc.) on components (such as the image sensor CM30) included in the camera module 2280. The image processed by the image signal processor (CM60) may be stored back in the memory CM50 for further processing or may be provided to external components of the camera module 2280 (the memory 2230, the display device 2260, the electronic device 2202, the electronic device 2204, the server 2208, etc.). The image signal processor CM60 may be integrated into the processor 2220 or configured as a separate processor operated independently of the processor 2220. When the image signal processor CM60 is configured as a processor separate from the processor 2220, an image processed by the image signal processor CM60 is subjected to additional image processing by the processor 2220 and then displayed on the display device 2260.

The electronic device 2201 may include a plurality of camera modules 2280 each having different properties or functions. In this case, one of the plurality of camera modules 2280 may be a wide-angle camera, and the other may be a telephoto camera. Similarly, one of the plurality of camera modules 2280 may be a front camera and the other may be a rear camera.

The image sensor according to an example embodiment may be applied to various electronic devices.

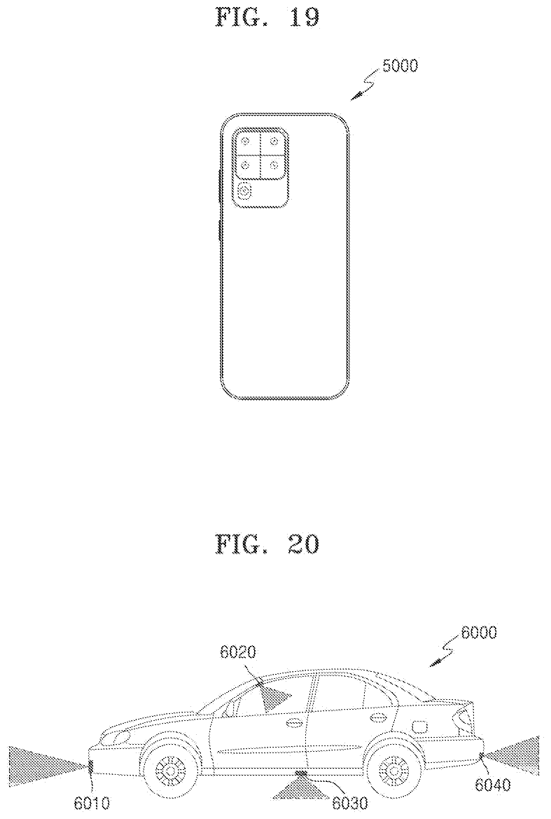

FIGS. 19 and 20 illustrate examples of an electronic device to which an image sensor according to an example embodiment is applied.

The image sensor according to an embodiment may be applied to various types of cameras provided in a mobile phone or smartphone 5000 illustrated in FIG. 19.

Also, the image sensor according to an example embodiment may be applied to a vehicle 6000 as shown in FIG. 20. The vehicle 6000 may include a plurality of vehicle cameras 6010, 6020, 6030, and 6040 disposed in various positions. Each of the vehicle cameras 6010, 6020, 6030, and 6040 may include an image sensor using the opto-electronic devices 10, 100, 200, 300, and 400 according to an example embodiment. Some of the plurality of vehicle cameras 6010, 6020, 6030, and 6040 provided in the vehicle 6000 may be cameras for acquiring a visible light image, and some thereof may be cameras for acquiring an infrared image for night use. By utilizing the plurality of vehicle cameras (6010, 6020, 6030, and 6040), various information on the interior or surroundings of the vehicle 6000 may be provided to a driver, and objects or people in an image may be automatically recognized to provide information required for autonomous driving.

In addition to this, the image sensor described above may be provided in personal digital assistant (PDA), laptop, personal computer (PC), home appliance, security camera, military camera, medical camera, or Internet of things (IoT) device, virtual reality device, augmented reality device, etc. By using the cameras mounted on these devices, images may be acquired in various environments, such as dark environments and environments that cannot be directly accessed by humans, and subjects in the images may be automatically identified. In addition, an augmented reality device may recognize a user environment and provide an additional image suitable for the user environment.

According to the QD film and the producing method thereof according to an example embodiment, in a state in which a QD array forming a thin film is formed, cross-linking is performed, and QD doping is then performed in the thin film state, and thus, a QD film in which an energy band level is changed by doping of QDs may be obtained, and an opt-electronic device and an image sensor capable of achieving low dark noise and high signal-to-noise ratio and obtaining a fast response rate may be realized using the QD film as a light absorption material.

In addition, according to the QD film and the producing method thereof according to an example embodiment, because QD doping is performed using a metal solution in a thin film state, a metal solution that does not contain DDA may be used as a doping solution, and thus, doping is possible for all types of QDs without limitation on a QD material, whether it is melted in a solvent, or a ligand type, and there is no damage to QDs during doping.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

1. A method for producing a quantum dot (QD) film, the method comprising:
applying a QD solution on a surface of a base portion to form a QD array;
performing cross-linking on the formed QD array;
doping QDs included in the QD array by reacting the QDs included in the QD array on which cross-linking is completed with a metal solution comprising a doping metal; and
cleaning the QD array to obtain a QD film comprising the doped QDs.

2. The method of claim 1, wherein the metal solution comprises a solution in which a doping metal precursor and didodecyldimethylammonium bromide (DDAB) are dissolved.

3. The method of claim 2, wherein the metal solution comprises a solution in which a metal salt comprising a doping metal and DDAB are added and dissolved.

4. The method of claim 3, wherein the metal salt comprises one of CuCl2, AgNO3, AgCl, and AuCl3.

5. The method of claim 1, wherein, the performing of cross-linking uses a solution in which a linker is dissolved.

6. The method of claim 5, wherein the linker comprises at least one of diamine and dithiol.

7. The method of claim 1, wherein the QD solution comprises at least one of organic ligand surfactant QDs, halide treated QDs, metal treated QDs, and metal chalcogenide complex treated QDs.

8. The method of claim 1, wherein the QDs of the QD solution are intrinsic n-type InAs or InSb QDs, and
wherein the doped QDs are of an n-type or p-type.

9. A quantum dot (QD) film comprising:
an array of QDs,
wherein the array of QDs is formed on a surface of a base portion, and
wherein the array of QDs comprises cross-links and doped QDs formed by reacting the QDs with a precursor of a doping metal.

10. The QD film of claim 9, wherein the array of QDs comprises a QD stack of two or more layers.

11. The QD film of claim 9, wherein the cross-link comprises at least one of diamine and dithiol.

12. The QD film of claim 9, wherein the QDs comprise at least one of organic ligand surfactant QDs, halide treated QDs, metal treated QDs, and metal chalcogenide complex treated QDs.

13. The QD film of claim 9, wherein the QDs are InAs or InSb QDs, and wherein the doping metal comprises one of Ag, Au, and Cu.

14. An opto-electronic device comprising:
a base portion;
a first electrode and a second electrode spaced apart from each other on an upper surface of the base portion; and
a quantum dot (QD) layer between the first electrode and the second electrode on the base portion, the QD layer comprising a plurality of QDs,
wherein the QD layer comprises the QD film comprising the doped QDs produced by the method of claim 1.

15. The opto-electronic device of claim 14, wherein the QDs included in the QD solution are of intrinsic n-type InAs or InSb QDs, and
wherein the doped QDs are of an n-type or p-type.

16. The opto-electronic device of claim 14, wherein the base portion comprises:
a first semiconductor layer doped with a first conductivity type; and
a second semiconductor layer disposed on an upper surface of the first semiconductor layer and doped with a second conductivity type different from the first conductivity type,
wherein the upper surface of the base portion corresponds to an upper surface of the second semiconductor layer,
wherein the first electrode and the second electrode are electrically connected to the second semiconductor layer, and
wherein the QD layer is between the first electrode and the second electrode on the second semiconductor layer and comprises QDs doped with a single conductivity type.

17. The opto-electronic device of claim 16, further comprising a first doped region and a second doped region spaced apart from each other in the second semiconductor layer and doped with a concentration different from a concentration of the second semiconductor layer,
wherein the first electrode and the second electrode are electrically connected to the first doped region and the second doped region, respectively.

18. An image sensor comprising:
an array of a plurality of opto-electronic devices; and
a driving circuit configured to output a signal from each of the opto-electronic devices,
wherein each of the opto-electronic devices comprises:
a base portion;
a first electrode and a second electrode spaced apart from each other on an upper surface of the base portion; and
a quantum dot (QD) layer between the first electrode and the second electrode on the base portion, the QD layer comprising a plurality of QDs,
wherein the QD layer comprises the QD film comprising the doped QDs produced by the method of claim 1.

19. The image sensor of claim 18, wherein the base portion comprises:
a first semiconductor layer doped with a first conductivity type; and
a second semiconductor layer disposed on an upper surface of the first semiconductor layer and doped with a second conductivity type different from the first conductivity type,
wherein the upper surface of the base portion corresponds to an upper surface of the second semiconductor layer,
wherein the first electrode and the second electrode are electrically connected to the second semiconductor layer, and
wherein the QD layer is between the first electrode and the second electrode on the second semiconductor layer and comprises QDs doped with the first conductivity type.

20. The image sensor of claim 19, further comprising a first doped region and a second doped region spaced apart from each other in the second semiconductor layer and doped with a concentration different from a concentration of the second semiconductor layer,
wherein the first electrode and the second electrode are electrically connected to the first doped region and the second doped region, respectively.
